(19) United States
(12) Patent Application Publication
(10) Pub. No.: US 2006/0099736 A1
(43) Pub. Date: May 11, 2006

(54) Flip chip underfilling

(76) Inventors: Mohan R. Nagar, Milpitas, CA (US); Mukul A. Joshi, Santa Clara, CA (US); Shirish Shah, San Ramon, CA (US)

Correspondence Address: LSI LOGIC CORPORATION, 1621 BARBER LANE, MS: D-106, MILPITAS, CA, 95035, US

(21) Appl. No.: 10/984,508

(22) Filed: Nov. 9, 2004

(51) Int. Cl. H01L 21/48; H01L 21/50; H01L 21/44; H01L 23/48; H01L 23/52; H01L 29/40

(52) U.S. Cl. 438/108; 257/778

(57) ABSTRACT

A method of underfilling an integrated circuit that is mounted to a first side of a package substrate having an opposing second side. A void is provided, which extends completely through the package substrate and is disposed under the integrated circuit. The package substrate is disposed with the second side up and the first side and the integrated circuit down. An underfill material is dispensed into the void on the second side of the package substrate. The underfill material thereby flows first through the void and then between the first side of the package substrate and the integrated circuit.

### FIELD

This invention relates to the field of integrated circuit fabrication. More particularly, this invention relates to underfilling mounted integrated circuits during packaging.

### BACKGROUND

Integrated circuits are typically packaged prior to use, to protect them from subsequent handling and the environment in which they will be used. As a part of the packaging process, some types of integrated circuits, such as flip chips, are typically under filled prior to encapsulation.

The underfilling process is intended to fill the gap that would otherwise exist between the surface of the flip chip and the surface of the substrate to which the flip chip is electrically connected. The electrical connections are made by small solder bumps which are placed between the flip chip and the substrate. Thus, it is the solder bumps that create the gap between the flip chip and the substrate.

The gap is typically under filled with a fluid material that is brought in contact with the edge of the gap. Capillary action wicks the fluid between the flip chip and the substrate, around the solder bumps, and filling the gap. However, various process parameters, such as contamination of one or both of the flip chip or substrate surfaces, impurity of the fluid material, or improper processing conditions, can result in an incomplete underfill of the flip chip. This may leave small pockets or voids within the gap where there is no underfill material.

If the underfill material is designed to help conduct heat away from the flip chip, the voids may result in hot spots in the flip chip during use, and ultimately device failure. The voids may also create stress concentrations resulting in fatigue cracking and functional failure from thermal cycling during normal functioning of the integrated circuit. Therefore, it is typically regarded as essential to have as complete an underfill as possible.

Another drawback of this customary, capillary action method of underfilling the flip chip is that it is by nature a very labor intensive process which is not readily given to automation. Thus, the process is prone to the yield loss inherent with manual processes, and also the relatively high cost that is typically associated with manual processes.

What is needed, therefore, is a method of packaging an integrated circuit that more readily lends itself to automation and reduces the occurrence of incomplete underfill.

### SUMMARY

The above and other needs are met by a method of underfilling an integrated circuit that is mounted to a first side of a package substrate having an opposing second side. A void is provided, which extends completely through the package substrate and is s disposed under the integrated circuit. The package substrate is disposed with the second side up and the first side and the integrated circuit down. An underfill material is dispensed into the void on the second side of the package substrate. The underfill material thereby flows first through the void and then between the first side of the package substrate and the integrated circuit.

In this manner, the underfill material that is dispensed through the void is able to push the air before the flow and out around the edges of the integrated circuit. Thus, the incidence of gaps and air pockets between the integrated circuit and the package substrate is dramatically reduced. Further, the underfilling process tends to go faster because the underfill material flows from under the integrated circuit toward the edges of the integrated circuit in all directions.

In various preferred embodiment according to this aspect of the invention, the void is centered under the integrated circuit. In some embodiments a plurality of voids is disposed under the integrated circuit, into which underfill material is dispensed. In one embodiment a vacuum is drawn around an edge of the integrated circuit between the integrated circuit and the first side of the package substrate. This assists the flow of the underfill material through the void and between the first side of the package substrate and the integrated circuit. Preferably, the void in the package substrate is plated. Also described is a packaged integrated circuit that is under filled according to the method.

According to another aspect of the invention there is described a method of underfilling an integrated circuit that is mounted to a first side of a package substrate having an opposing second side. A void extends completely through the package substrate, and is disposed under the integrated circuit. An underfill material is dispensed around an edge of the integrated circuit between the integrated circuit and the first side of the package substrate. A vacuum is drawn through the void on the second side of the package substrate between the integrated circuit and the first side of the package substrate. This assists the flow of the underfill material between the first side of the package substrate and the integrated circuit and through the void. The underfill material thereby flows first between the first side of the package substrate and the integrated circuit and then through the void.

In various embodiments according to this aspect of the invention, the void is centered under the integrated circuit. In some embodiments, a plurality of voids are disposed under the integrated circuit. One embodiment applies a pressure around an edge of the integrated circuit between the integrated circuit and the first side of the package substrate, and thereby assists the flow of the underfill material between the first side of the package substrate and the integrated circuit and through the void. Preferably, the void in the package substrate is plated. Also described is a packaged integrated circuit that is under filled according to the method.

According to yet another aspect of the invention the is described a package substrate having a second side that receives an integrated circuit on an opposing first side. A void extends from the first side to the second side, and has a diameter sufficient to permit a flow of an underfill material through the void using only at least one of gravity and capillary action. In various embodiments according to this aspect of the invention, the void in the package substrate is plated. The void is preferably centered in an area adapted to receive the integrated circuit. In some embodiments the void is a plurality of voids.

### BRIEF DESCRIPTION OF THE DRAWINGS

Further advantages of the invention are apparent by reference to the detailed description when considered in conjunction with the figures, which are not to scale so as to more clearly show the details, wherein like reference numbers indicate like elements throughout the several views, and wherein:

FIG. 1 is a cross sectional depiction of an integrated circuit mounted to a package substrate, and being under filled according to a first embodiment of the present invention.

FIG. 2 is a cross sectional depiction of an integrated circuit mounted to a package substrate, and being under filled according to a second embodiment of the present invention.

FIG. 3 is a cross sectional depiction of an integrated circuit mounted to a package substrate, and being under filled according to a third embodiment of the present invention.

### DETAILED DESCRIPTION

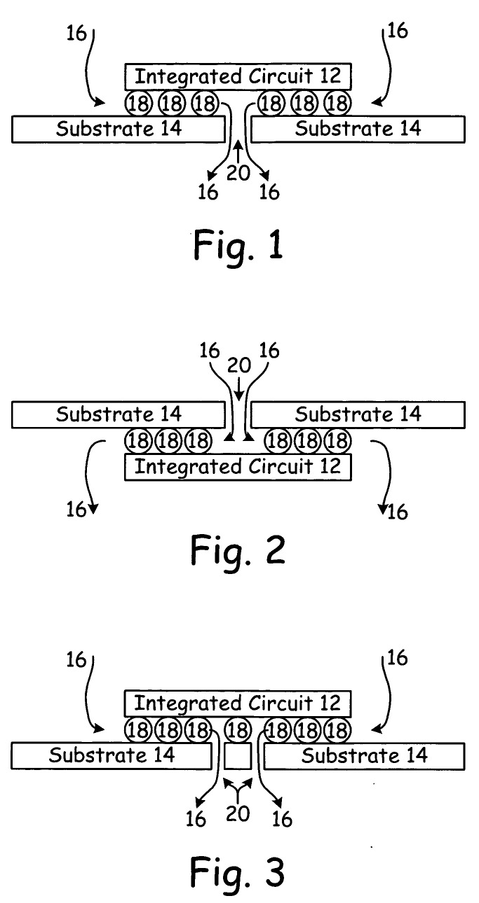

With reference now to FIG. 1, there is depicted a cross sectional diagram of an integrated circuit 12 that is mounted to a package substrate 14, such as by solder bumps 18. In this embodiment, underfill material 16 is dispensed at one or more edges around the side of the integrated circuit 12, and flows toward the center of the integrated circuit 12 and out through a void 20 that is formed completely through the substrate 14. The motive force for the flow of the underfill material 16 can be merely gravity and capillary action, but is most preferably a vacuum that is drawn on the void 20, such as from the underside of the substrate 14. A pressure can also be applied on the dispensing side of the underfill material 16.

FIG. 2 depicts a second embodiment, where the assembly is disposed so that the integrated circuit 12 is below the package substrate, and the underfill material 16 is dispensed through the void 20, and then flows between the substrate 14 and the integrated circuit 12, and out around the edges of the integrated circuit 12. The motive force for the flow of the underfill material 16 can be provided merely by gravity and capillary action, or a pressure can be applied on the inlet of the underfill material 16 through the void 20. Alternately, a vacuum can be drawn at the outlet of the underfill material 16 around the edges of the integrated circuit 12.

FIG. 3 depicts a third embodiment, where there are more than one void 20. Although depicted in regard to the first embodiment of FIG. 1, it is appreciated that the second embodiment as depicted in FIG. 2 is also adaptable so as to employ more than one void 20. Preferably, the void 20 is of a sufficiently large diameter so that the underfill material 16 can flow through it using only at least one of gravity and capillary action, for those embodiments which rely on such. Alternately, the void 20 can have any diameter that is desired within the constraints of the functions of the substrate 14. The void 20 is preferably plated, such as with a conductive material, as may be used on conductive through holes within the substrate 14. Alternately, the void 20 is plated with some other material that allows the underfill material 16 to flow smoothly across it.

In this manner, the various embodiments of the present invention enable the underfill material 16 to flow between the integrated circuit 12 and the substrate 14 in a manner that reduces the incidence of voids in the underfill material 16 between the substrate 14 and the integrated circuit 12. In addition, by adding one or both of pressure on the dispensing side and vacuum on the exiting side, the underfill process can be accomplished in a shorter length of time.

The foregoing description of preferred embodiments for this invention has been presented for purposes of illustration and description. It is not intended to be exhaustive or to limit the invention to the precise form disclosed. Obvious modifications or variations are possible in light of the above teachings. The embodiments are chosen and described in an effort to provide the best illustrations of the principles of the invention and its practical application, and to thereby enable one of ordinary skill in the art to utilize the invention in various embodiments and with various modifications as are suited to the particular use contemplated. All such modifications and variations are within the scope of the invention as determined by the appended claims when interpreted in accordance with the breadth to which they are fairly, legally, and equitably entitled.

What is claimed is:

1. A method of underfilling an integrated circuit mounted to a first side of a package substrate having an opposing second side, the method comprising the steps of:
providing a void extending completely through the package substrate and disposed under the integrated circuit,
disposing the package substrate with the second side up and the first side and the integrated circuit down,
dispensing an underfill material into the void on the second side of the package substrate,
the underfill material thereby flowing first through the void and then between the first side of the package substrate and the integrated circuit.

2. The method of claim 1, wherein the void is centered under the integrated circuit.

3. The method of claim 1, further comprising a plurality of voids disposed under the integrated circuit and into which underfill material is dispensed.

4. The method of claim 1, further comprising drawing a vacuum around an edge of the integrated circuit between the integrated circuit and the first side of the package substrate, and thereby assisting the flow of the underfill material through the void and between the first side of the package substrate and the integrated circuit.

5. The method of claim 1, wherein the void in the package substrate is plated.

6. A packaged integrated circuit under filled according to the method of claim 1.

7. A method of underfilling an integrated circuit mounted to a first side of a package substrate having an opposing second side, the method comprising the steps of:
providing a void extending completely through the package substrate and disposed under the integrated circuit,
dispensing an underfill material around an edge of the integrated circuit between the integrated circuit and the first side of the package substrate,
drawing a vacuum through the void on the second side of the package substrate between the integrated circuit and the first side of the package substrate, and thereby assisting the flow of the underfill material between the first side of the package substrate and the integrated circuit and through the void,
the underfill material thereby flowing first between the first side of the package substrate and the integrated circuit and then through the void.

8. The method of claim 7, wherein the void is centered under the integrated circuit.

9. The method of claim 7, further comprising a plurality of voids disposed under the integrated circuit and through which a vacuum is drawn.

10. The method of claim 7, further comprising applying a pressure around an edge of the integrated circuit between the integrated circuit and the first side of the package substrate, and thereby assisting the flow of the underfill material between the first side of the package substrate and the integrated circuit and through the void.

11. The method of claim 7, wherein the void in the package substrate is plated.

12. A packaged integrated circuit under filled according to the method of claim 7.

13. In a package substrate having a second side and adapted to receive an integrated circuit on an opposing first side, the improvement comprising a void extending from the first side to the second side, and having a diameter sufficient to permit a flow of an underfill material through the void using only at least one of gravity and capillary action.

14. The package substrate of claim 13, wherein the void in the package substrate is plated.

15. The package substrate of claim 13, wherein the void is centered in an area adapted to receive the integrated circuit.

16. The package substrate of claim 13, wherein the void comprises a plurality of voids.
